(19) United States
(12) Patent Application Publication
(10) Pub. No.: US 2026/0081596 A1
(43) Pub. Date: Mar. 19, 2026

(54) SMART MULTI-STAGE POWER DRIVE

(71) Applicant: Alpha and Omega Semiconductor International LP, Toronto (CA)

(72) Inventors: Ziwei Yu, Cupertino, CA (US); Sitthipong Angkititraku, Dublin, CA (US); Jian Yin, San Ramon, CA (US); Lin Chen, San Jose, CA (US)

(73) Assignee: Alpha and Omega Semiconductor International LP, Toronto (CA)

(21) Appl. No.: 19/300,770

(22) Filed: Aug. 15, 2025

Related U.S. Application Data
(63) Continuation-in-part of application No. 18/887,209, filed on Sep. 17, 2024.

(51) Int. Cl. H03K 17/16; H03K 17/082

(52) U.S. Cl. CPC H03K 17/165; H03K 17/0822; H03K 2217/0027; H03K 2217/0063; H03K 2217/0072

(57) ABSTRACT

Apparatus and associated methods relate to a gate drive timing controller (GDTC). In an illustrative example, the GDTC may include a control output configured to generate a power stage activation signal (PSAS) to control a power stage output. For example, the control output may be operably coupled to a switch device having a power MOSFET for delivering power and a sense FET. In some embodiments, the GDTC may include a timing control logic (TCL) configured to generate the PSAS. For example, the TCL may include three pullup transistors and three pulldown transistors. For example, gate terminals of the three pullup transistors and the three pulldown transistors are separately controlled by the TCL as a function of the sense voltage related to a source voltage of the power MOSFET. Various embodiments may advantageously allow an adaptive generation of the PSAS based on a sensed output current from the power MOSFET.

### CROSS-REFERENCE TO RELATED APPLICATIONS

This application is a Continuation-In-Part and claims the benefit of U.S. application Ser. No. 18/887,209, titled “Multi-Stage Adaptive Gate Drive Control,” filed by Ziwei Yu, et al., on Sep. 17, 2024.

This application incorporates the entire contents of the foregoing application(s) herein by reference.

### TECHNICAL FIELD

Various embodiments relate generally to power electronics and circuit control.

### BACKGROUND

A hard switching power converter (HSPC) may include power electronics configured to manage the conversion of electrical energy between different voltage levels. In some examples, the HSPC may control switch transitions between on and off states while maintaining a load current supplied to a (high power) load. In some examples, the HSPC may include a half-bridge configuration. For example, the half-bridge configuration may include two switches (e.g., two metal-oxide-semiconductor field-effect transistors (MOSFETs)) connected in series between the power supply and ground. For example, a junction between these two switches may form a switching node, which defines the output voltage or current supplied to the load.

The switch node voltage, for example, may include a voltage present at the junction between the two MOSFETs in the half-bridge configuration. This voltage, for example, may influence the voltage supplied to the load. The load, for example, may be connected between the switch node and ground. In some examples, the load may be connected between the switch node and the positive power supply. The behavior of the switch node voltage during the switching events of the MOSFETs may determine an (transient and/or steady-state) output power of the HSPC.

In high-power applications, for example, the HSPC may include multiple MOSFETs in parallel. For example, parallel-connected MOSFETs may include varying response characteristics amongst the MOSFETs (e.g., different parasitic impedance, voltage thresholds).

### SUMMARY

Apparatus and associated methods relate to a gate drive timing controller (GDTC). In an illustrative example, the GDTC may include a control output configured to generate a power stage activation signal (PSAS) to control a power stage output. For example, the control output may be operably coupled to a switch device having a power MOSFET for delivering power and a sense FET. In some embodiments, the GDTC may include a timing control logic (TCL) configured to generate the PSAS. For example, the TCL may include three pullup transistors and three pulldown transistors. For example, gate terminals of the three pullup transistors and the three pulldown transistors are separately controlled by the TCL as a function of the sense voltage related to a source voltage of the power MOSFET. Various embodiments may advantageously allow an adaptive generation of the PSAS based on a sensed output current from the power MOSFET.

Apparatus and associated methods relate to a gate drive timing controller (GDTC). In an illustrative example, the GDTC may generate a power stage activation signal (PSAS) to control an output current of a MOSFET(s) of the power stage. Three pullup transistors, for example, may be electrically connected to the control output in parallel, configured to generate the PSAS as a function of a switch node voltage (Vsw) and a source inductance voltage (VLS) of the MOSFET. For example, a first pullup transistor may be activated when a PWM signal for the power stage is received, and deactivated based on the VLS. For example, a second pullup transistor may be synchronized with the PWM signal. For example, a third pullup transistor may be activated when the Vsw is detected. Various embodiments may advantageously generate the PSAS adaptively to reduce turn-on loss of the MOSFET while keeping a low transient voltage spike.

Various embodiments may achieve one or more advantages. Some embodiments, for example, may advantageously reduce the switching loss without sacrificing a transient voltage spike requirement. For example, some embodiments may advantageously generate a sense signal with a predetermined magnitude during a design phase. Some embodiments, for example, may advantageously reduce time delay for a corresponding feedback signal to be received by the timing control logic. For example, some embodiments may advantageously reduce a turn-on loss at (e.g., parallel connected) MOSFETs of the power stage. Some embodiments may, for example, advantageously provide better noise immunity properties. For example, some embodiments may advantageously adapt the power stage activation signals to different loading currents automatically. For example, some embodiments may advantageously reduce a turn-off loss at (e.g., parallel connected) MOSFETs of the power stage. For example, some embodiments may advantageously adapt the power stage deactivation signals to different loading currents automatically. Some embodiments may, for example, advantageously provide a damping effect following the first stage. For example, some embodiments may advantageously reduce gate voltage overshoot. Some embodiments, for example, may advantageously be adaptively controlled across different phases of switching based on real-time device response. For example, some embodiments may advantageously prevent excessive gate undershoot and/or oscillation. For example, some embodiments may advantageously provide a fast turn-off enhancement after the switching node voltage slew.

The details of various embodiments are set forth in the accompanying drawings and the description below. Other features and advantages will be apparent from the description and drawings, and from the claims.

### BRIEF DESCRIPTION OF THE DRAWINGS

FIG. 1A depicts a first embodiment of an exemplary adaptive power control system (APCS) employed in an illustrative use-case scenario.

FIG. 1B depicts a second embodiment of an exemplary APCS employed in an illustrative use-case scenario.

FIG. 2 depicts an exemplary electrical schematic of a multi-stage gate control circuit (MSGCC).

FIG. 3 is a block diagram depicting an exemplary time control logic.

FIG. 4 is a flowchart illustrating an exemplary adaptive power stage activation signals generation method.

FIG. 5 depicts an electrical schematic of an exemplary MSGCC including a multi-stage turn-off timing scheme.

FIG. 6 is a block diagram depicting an exemplary time control logic for a multi-stage turn-off timing scheme.

FIG. 7 is an electrical schematic of an exemplary MSGCC having an exemplary Sense-FET Incorporated Device (SFID).

FIG. 8 is a block diagram depicting an exemplary time control turn-on logic.

FIG. 9 is a block diagram depicting an exemplary time control turn-off logic.

FIG. 10 is a flowchart illustrating an exemplary adaptive power stage turn-on method.

FIG. 11 is a flowchart illustrating an exemplary adaptive power stage turn-off method

Like reference symbols in the various drawings indicate like elements.

### DETAILED DESCRIPTION OF ILLUSTRATIVE EMBODIMENTS

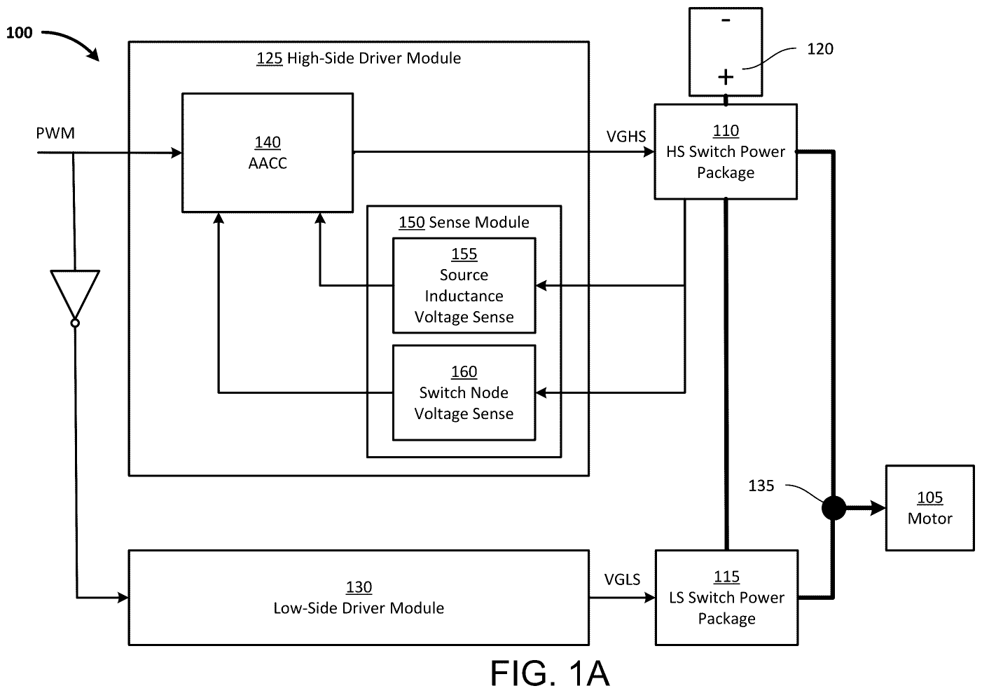

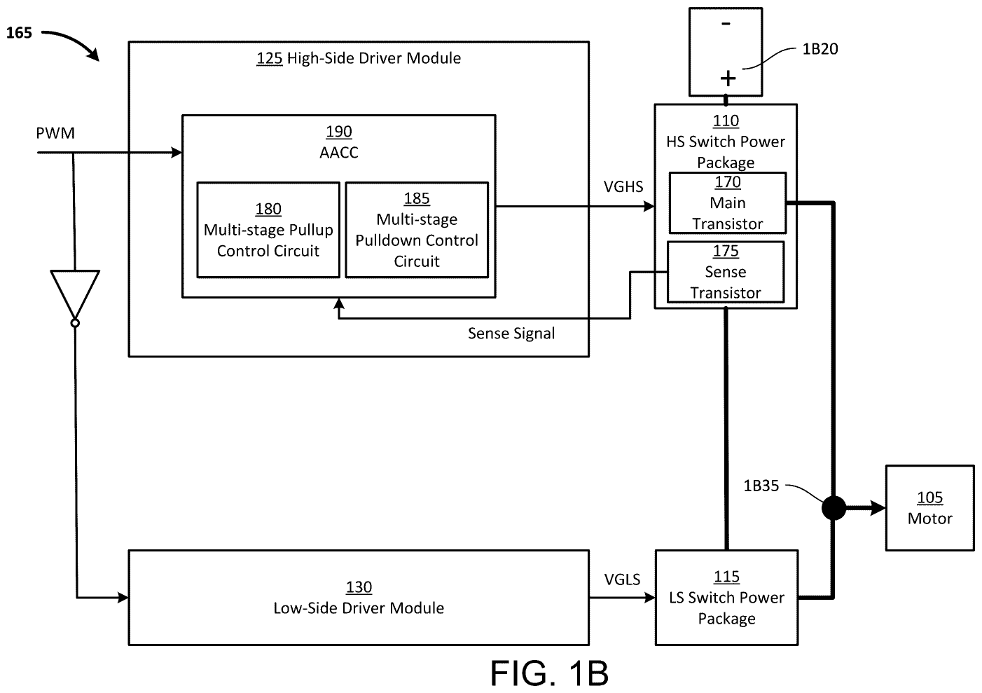

FIG. 1A depicts a first embodiment of an exemplary adaptive power control system (APCS) employed in an illustrative use-case scenario. In the depicted example, an APCS 100 includes a motor 105 electrically connected to a high-side switch power package (HSPP 110) and a low-side switch power package (LSPP 115). For example, the HSPP 110 and the LSPP 115 may include a silicon (Si) power device.

For example, the motor 105 may include a hard switching power converter configured to supply power to the motor 105. For example, the HSPP 110 and the LSPP 115 may be configured in a half-bridge topology. In some implementations, the motor 105 may include a high power application. For example, the motor 105 may include a high power alternative current (AC) motor.

In some implementations, the HSPP 110 and the LSPP 115 may include a switching circuit. The HSPP 110 and the LSPP 115, in this example, are connected in series to receive power from an DC power source 120. In some implementations, the HSPP 110 and the LSPP 115 may include multiple parallel connected switch transistors (e.g., metal-oxide-semiconductor field-effect transistors (MOSFETs)) configured to supply a high current to the motor 105. For example, the HSPP 110 may include multiple power MOSFETs connected in parallel. For example, each of the power MOSFET may include a source terminal operably coupled to the DC power source 120.

In some implementations, multiple MOSFETs connected in parallel may share a current load to the motor 105. For example, the multiple MOSFETs connected in parallel may advantageously reduce an overall on-resistance (Rds(on)) of the APCS 100. In some examples, the HSPP 110 and the LSPP 115 may be implemented on a printed circuit board (PCB).

As shown, the HSPP 110 receives a first switch control signal (VGHS) from a high-side power driving circuit (HDM 125), and the LSPP 115 receives a second switch control signal (VGLS) from a low-side power driving circuit (LDM 130). For example, the HDM 125 and the LDM 130 may be configured to control the HSPP 110 and the LSPP 115 to maintain a voltage and current at a switch node 135 at a level suitable for the motor 105. For example, the APCS 100 may be configured to generate the VGHS and the VGLS based on a turn-on driving scheme in motor drive application.

As shown, the HDM 125 receives a control input (a pulse width modulation (PWM) signal). The HDM 125 includes an auto-adaptive control circuit (AACC 140) to generate the VGHS to the HSPP 110 as a function of the PWM signal. In some implementations, the AACC 140 may include timing control logic to generate VGHS based on sense input from a sense module 150.

The sense module 150 includes a source inductance voltage sense 155 and a switch node voltage sense 160. For example, the switch node voltage sense 160 may be configured to sense (e.g., detect based on a predetermined voltage threshold) at the switch node 135. In some implementations, the source inductance voltage sense 155 may be configured to measure a bond-wire voltage of the MOSFET in the HSPP 110. In some implementations, the source inductance voltage sense 155 may be configured to measure a copper clip voltage of the MOSFET in the HSPP 110. For example, the source inductance voltage sense 155 may sense a voltage across a capacitor inductance of the bond wire in a package of the HSPP 110. In some examples, the source inductance voltage sense 155 may sense a voltage across inductors connected to a source terminal parasitic inductance of a PCB trace of the HSPP 110.

In some implementations, the AACC 140 may be configured to, upon activated by the PWM signal, adaptively time-control the VGHS based on a transient response at the switch node 135 and a source inductance voltage of the HSPP 110. In some examples, the AACC 140 may advantageously control switching loss of the HSPP 110 without sacrificing voltage spike during the transient state of the HSPP 110.

As an illustrative example without limitation, in medium-voltage and/or high-voltage hard-switching power converter topologies, there may be a trade-off between voltage spike and/or electromagnetic interference (EMI) requirement and switching loss when tuning the gate drive speed. For example, the AACC 140 may be configured to adaptively adjust, based on the source inductance voltage sense 155 and the switch node voltage sense 160, a turn-on speed of the HSPP 110 to limit a voltage spike during a transient from an OFF state to an ON state at the MOSFETs of the HSPP 110. Various embodiments may advantageously reduce a turn-on loss at (e.g., parallel connected) MOSFETs in the APCS 100.

In some implementations, the APCS 100 may be configured to include multiple power stages (e.g., including a high-side and a low-side). For example, the multiple power stages may be activated by multi-stage turn-on power stage activation signals (e.g., the VGHS and the VGLS). In some implementations, the multi-stage turn-on power stage activation signals may be generated by the AACC 140 based on a sensed MOSFET source inductance voltage and switching node voltage. Various implementations may advantageously adapt the power stage activation signals to different loading current automatically (e.g., for AC motor drive applications). In some examples, the AACC 140 may be configured to reduce switching loss without sacrificing a voltage spike requirement of the HSPP 110.

In various implementations, a gate drive timing control unit (e.g., the APCS 100) may include a control output (e.g., the VGHS) operably coupled to a gate terminal of a power metal-oxide-semiconductor field-effect transistor (power MOSFET), and is configured to generate a power stage activation signal to control a power stage (e.g., the HSPP 110) of the gate drive timing control unit. For example, the PWM signal may be configured to control an output current of the power MOSFET to a load (e.g., the motor 105). For example, a sense circuit (e.g., the sense module 150) may be coupled to the power MOSFET to measure a switch node voltage and a source inductance voltage of the power MOSFET. For example, the gate drive timing control unit may include an auto-adaptive control circuit (e.g., the AACC 140) configured to generate the power stage activation signal as a function of the switch node voltage and the source inductance voltage. For example, the power stage activation signal may be adaptively generated as a function of dynamic load conditions to reduce turn-on loss of the power MOSFET while keeping a low transient voltage spike.

FIG. 1B depicts a second embodiment of an exemplary APCS 165 employed in an illustrative use-case scenario. In this example, a HSPP 195 includes a main transistor 170 and a sense transistor 175. For example, the sense transistor 175 may include a Sense field effect transistor (Sense-FET). In some implementations, the VGHS signal may be transmitted to a corresponding gate terminal of the main transistor 170 and the sense transistor 175. For example, the main transistor 170 may supply a load current to the motor 105. For example, the sense transistor 175 may generate a sensed signal as a function of the load current to the AACC 140. In some examples, the sense transistor 175 may generate a current that is a predetermined fraction of the load current generated at the main transistor 170. For example, the sense transistor 175 may advantageously generate the sensed signal having a predetermined magnitude (e.g., resolution) by adjusting a sense resistor in a design phase.

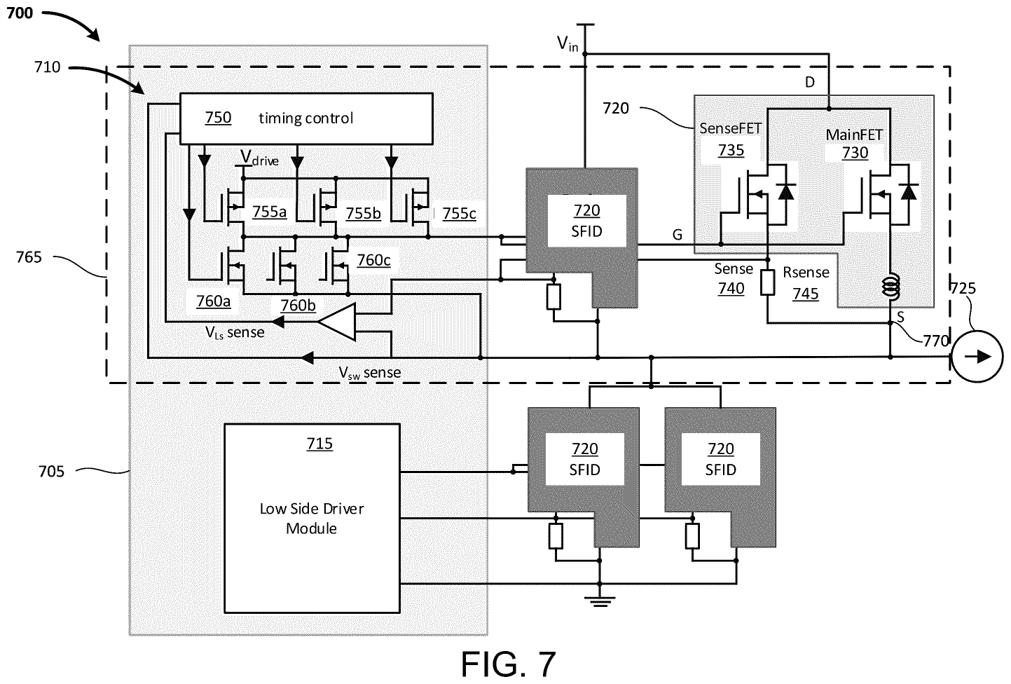

In the depicted example, an AACC 190 includes a multi-stage pullup control circuit 180 and a multi-stage pulldown control circuit 185. In some examples, the multi-stage pullup control circuit 180 and the multi-stage pulldown control circuit 185 may generate timing signals (e.g., components of the VGHS) to reduce a MOSFET switching loss while keeping the transient voltage spike low. For example, the multi-stage pullup control circuit 180, and the multi-stage pulldown control circuit 185 may generate the timing signals based on the sensed signals from the sense transistor 175. Accordingly, for example, the AACC 190 may adaptively generate the timing signals for a multi-stage driving scheme under different load conditions. Various implementations of the AACC 190 and the HSPP 195 are described in further details with reference to FIGS. 7-11.

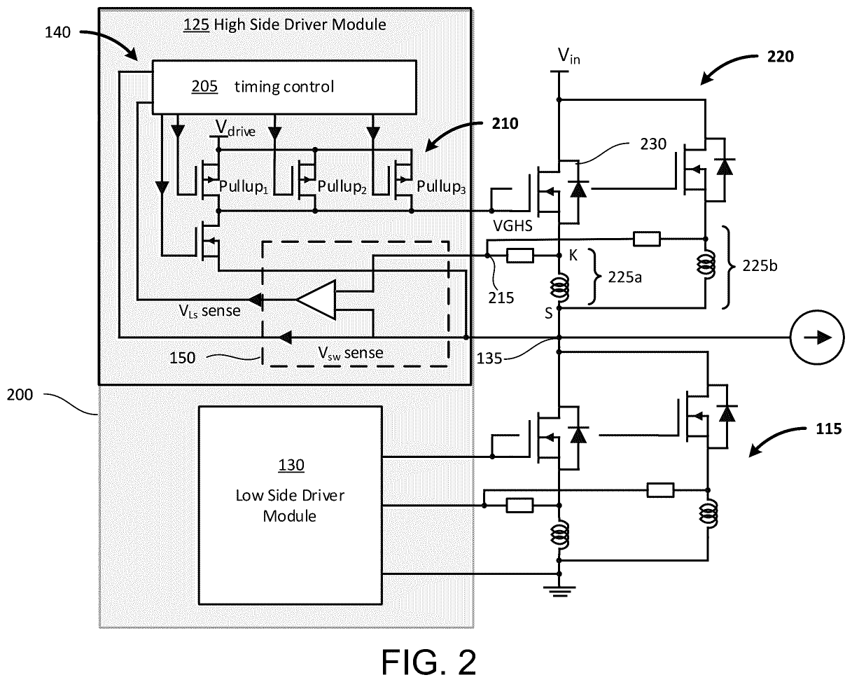

FIG. 2 depicts an exemplary electrical schematic of a multi-stage gate control circuit (MSGCC). In this example, the MSGCC 200 includes the HDM 125 and the LDM 130. Some electronic components of the HDM 125 are depicted in FIG. 2. In some examples, the LDM 130 may include a similar electronic structure (e.g., and/or a mirror image thereof) to the HDM 125.

In the depicted example, the AACC 140 of the 125/includes a timing control logic 205 and three pullup MOSFETs 210 (pullup1, pullup2, and pullup3). In some implementations, the timing control logic 205 may generate pull up stage signals to (independently) control the three pullup MOSFETs 210. For example, the timing control logic 205 may be activated by the PWM signal. For example, the gate terminals of a power MOSFET 230 in the HDM 125 may receive a control signal of a combined (e.g., aggregate) output from the three pullup MOSFETs 210. As shown, the timing control logic 205 may receive inputs from the sense module 150.

In this example, the sense module 150 may be configured to sense a MOSFET source bond-wire (e.g., a clip voltage) at a source bond-wire point 215, and a voltage at the switch node 135. For example, the source inductance voltage sense 155 may be configured to be determined based on a comparison between the switch node voltage at the switch node 135 and the bond-wire voltage at the source bond-wire point 215.

As shown, the HDM 125 may generate the VGHS by connecting source terminals of the three pullup MOSFETs 210 (Pullup1, Pullup2, and Pullup3 as shown in this example) in parallel to gate terminals of each parallel connected power MOSFET of a high-side switch (HS switch 220). For example, the HSPP 110 may include the HS switch 220. As shown, each of the power MOSFETs of the HS switch 220 may include a different parasitic inductance and resistance 225a, 225b. For example, a voltage across k and s may be a sensing voltage for the voltage drop across the source inductance. For example, the source inductance may indicate a change of current flowing through a MOSFET source terminal of the HS switch 220.

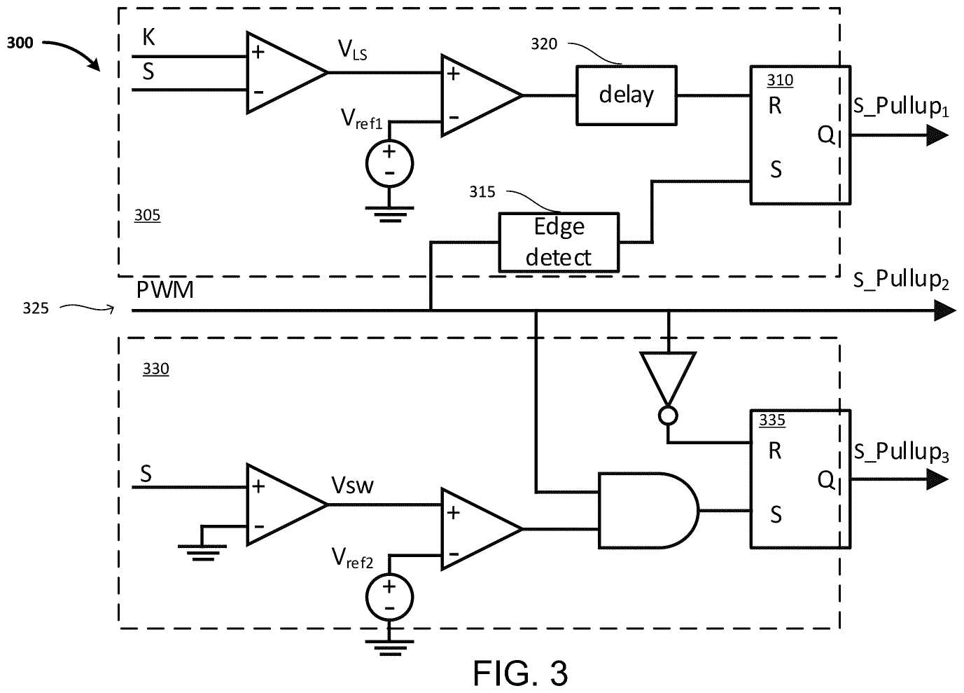

FIG. 3 is a block diagram depicting an exemplary time control logic 300. For example, the timing control logic 205 may include the time control logic 300. As shown, the time control logic 300 includes three outputs, S_pullup1, S_pullup2, and S_pullup3. For example, each of the S_pullup1, S_pullup2, and S_pullup3 may control each of the three pullup MOSFETs 210, pullup1, pullup2, and pullup3, respectively.

For example, the time control logic 300 may be configured to generate the power stage activation signals (VGHS of FIG. 1A) for a multi-stage driving scheme to reduce the MOSFET turn-on loss while keeping the transient voltage spike low. For example, the time control logic 300 may be configured to adaptively generate the power stage activation signals for a multi-stage driving scheme under different load conditions.

As shown, a first stage 305 includes a set-reset latch (SR latch 310). For example, the S_pullup1 may be configured to activate the pullup1 MOSFET when the SR latch 310 is in a set state. As shown, the SR latch 310 is set by an edge detect 315 of the PWM signal (e.g., as described with reference to FIG. 1A). For example, the first stage 305 may be a fast turn-on state started by the PWM signal. For example, the first stage 305 may include a low pullup resistor to facilitate a fast turn-on response. In the depicted example, the first stage 305 may be ended by a detection of the source inductance voltage. For example, the source inductance voltage may be determined by a detection of VLS larger than a predetermined reference voltage (Vref1). In this example, the SR latch 310 may be reset after a predetermined delay 320 upon the source inductance voltage is detected.

The time control logic 300 includes a second stage 325. In some implementations, the second stage 325 may be configured as a damping stage. For example, the second stage 325 may be connected to a high pullup resistor. For example, the second stage 325 may be synchronized with the PWM signal.

The time control logic 300 includes a third stage 330. In some implementations, the third stage 330 may be configured as a fast-enhance stage. As shown, the third stage 330 includes a second SR latch 335. For example, the third stage 330 may be activated by a detection of the switching node voltage. In some examples, the third stage 330 may speed up (e.g., promote) turn-on of the HDM 125 after detecting a switching node voltage slew.

As shown, the S_pullup3 is set by a detection of the switch node voltage above a predetermined second reference voltage (Vref2) and the PWM signal. The S_pullup3 is reset by an inverse of the PWM signal (e.g., when the power stage is deactivated). In some implementations, the third stage 330 may be activated by a control logic based on the source inductance voltage VLS.

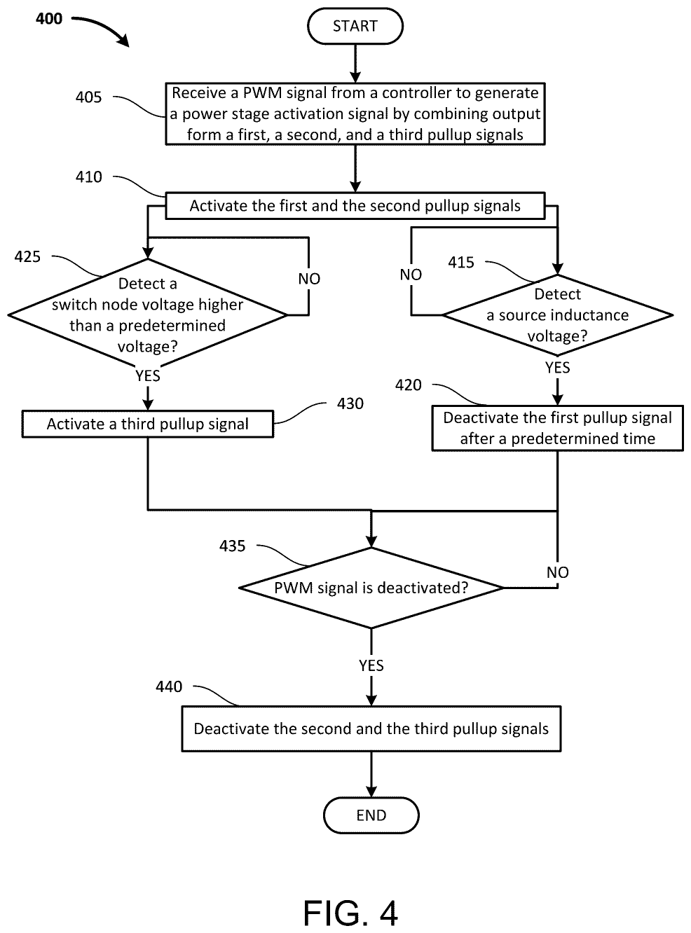

FIG. 4 is a flowchart illustrating an exemplary adaptive power stage activation signals generation method. For example, a method 400 may be performed by the time control logic 300. In this example, the method 400 begins in step 405 when a PWM signal is received from a controller to generate a power stage activation signal by combining output from a first, a second, and a third pullup signals. For example, the time control logic 300 of the AACC 140 may receive the PWM signal received by the AACC 140.

In step 410, the first and the second pullup signals are activated. For example, the time control logic 300 may activate the S_pullup1 and S_pullup2 signals to drive the pullup MOSFETs 210.

At a decision point 415, it is determined whether a source inductance voltage is detected. For example, the time control logic 300 may compare the sensed source inductance voltage with a predetermined threshold. If the source inductance voltage is detected, the first pullup signal is deactivated after a predetermined time in step 420. For example, the time control logic 300 may deactivate S_pullup1 after a delay based on the sensed source inductance voltage. If the source inductance voltage is not detected, the decision point 415 is repeated.

Operating in parallel, after the step 410, it is determined whether a switch node voltage higher than a predetermined voltage is detected at a decision point 425, it is determined whether a switch node voltage higher than a predetermined voltage is detected. For example, the time control logic 300 may check if the switch node voltage (e.g., the V_SW_sense signal) exceeds a set reference voltage. If the switch node voltage is higher than the predetermined voltage, in step 430, a third pullup signal is activated. For example, the time control logic 300 may activate S_pullup3 to speed up the turn-on of the HS switch 220. If the switch node voltage is not higher than a predetermined voltage, the decision point 425 is repeated.

At a decision point 435, it is determined whether the PWM signal is deactivated. For example, the time control logic 300 may check if the PWM signal is no longer active. If the PWM signal is deactivated, in step 440, the second and the third pullup signals are deactivated. For example, the time control logic 300 may deactivate S_pullup2 and S_pullup3 to turn off the corresponding pullup MOSFETs 210, and the method 400 ends.

Although some exemplary control methods are described using a multi-stage turn-on of the connected power semiconductor devices, multi-stage turn-off schemes based on source inductance voltage may be used to control a timing of gate signals. For example, a multi-stage turn-off control logic may be implemented independent of and/or together with the multi-stage turn on scheme.

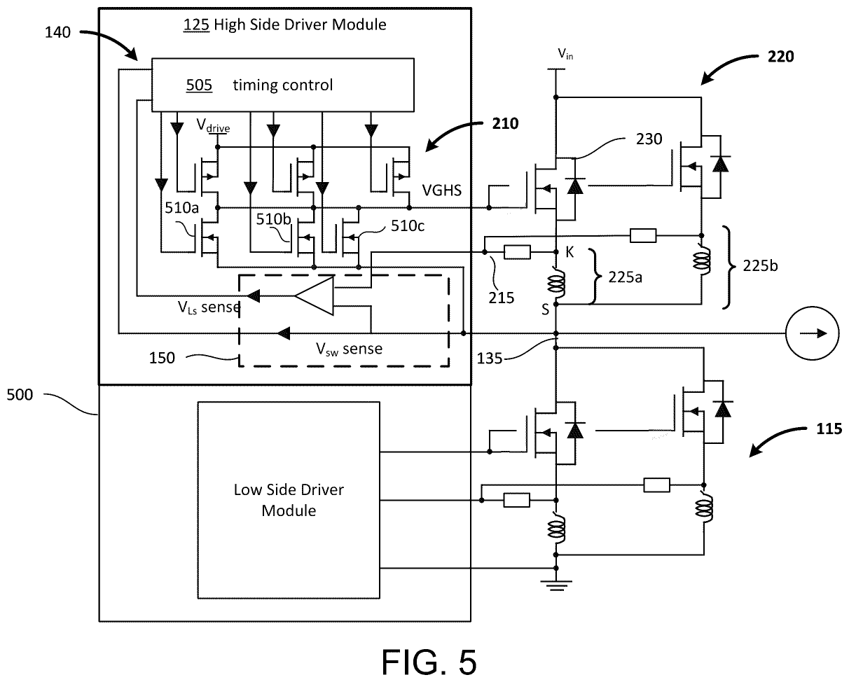

FIG. 5 depicts an exemplary electrical schematic of a MSGCC including a multi-stage turn-off timing scheme. In this example, a MSGCC 500 includes a timing control logic 505 operably coupled to the three pullup MOSFETs 210 and three pulldown MOSFETs 510a, 510b, and 510c. For example, the timing control logic 505 may control the three pullup MOSFETs 210 according to a timing logic described with reference to FIGS. 2-3.In various implementations, the timing control logic 505 may adaptively control a gate-turn off signal based on a PWM signal and a sensed source inductance voltage VLS_Sense. For example, the timing control logic 505 may advantageously reduce a turn-off loss at (e.g., parallel connected) MOSFETs of a power stage (e.g., the HS switch 220). For example, upon activation, the three pulldown MOSFETs 510a, 510b, and 510c may pulldown the power stage activation. For example, some embodiments may advantageously adaptively control a turn-off scheme of the power stage activation signals to different loading current automatically.

In some implementations, a gate control signal (e.g., the VGHS) may be generated as an aggregation of outputs of three pulldown MOSFETs 510a, 510b, and 510c. For example, when the power stage (e.g., the HS switch 220) is turned off by the PWM signal, the gate control signal may be generated in three stages. For example, in a first stage, the gate control signal may include a first turn-off signal configured to trigger a fast response at a power MOSFET controlled by the gate control signal (e.g., the power MOSFET 230). For example, in a second stage, the gate control signal may include a damping signal configured to reduce voltage spike at the power MOSFET. For example, in a third stage, the gate control signal may include a fast turn-off signal configured to speed up (e.g., promote) turn-off of the power MOSFET after the first voltage peak during the switching transient (e.g., the voltage spike at the second stage).

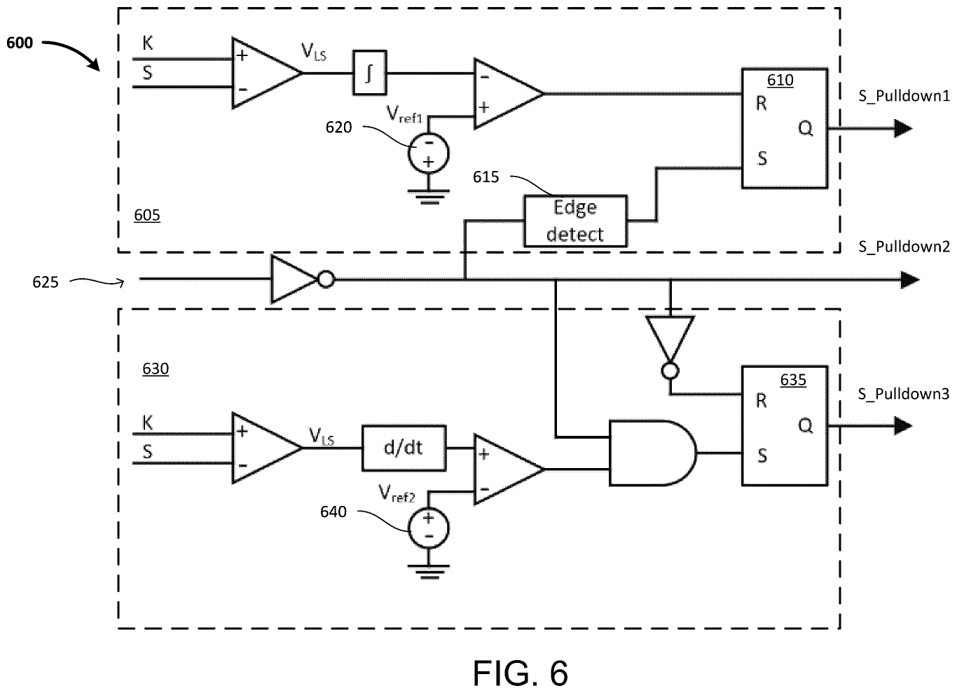

FIG. 6 is a block diagram depicting an exemplary time control logic 600 for a multi-stage turn-off timing scheme. For example, the timing control logic 505 may include the time control logic 600. As shown, the time control logic 600 includes three outputs, S_pulldown1, S_pulldown2, and S_pulldown3. For example, each of the S_pulldown1, S_pulldown2, and S_pulldown3 may control each of the three pulldown MOSFETs 510a, 510b, and 510c, respectively.

For example, the time control logic 600 may be configured to generate the power stage gate signals for a multi-stage driving scheme to reduce the MOSFET turn-off loss while keeping the transient voltage spike low. For example, the time control logic 600 may be configured to adaptively generate the power stage gate signals for a multi-stage driving scheme under different load conditions.

In this example, a first pulldown stage 605 includes a set-reset latch (SR latch 610). For example, the S_pulldown1 may be configured to pull down the gate voltage at the HS switch 220 when the SR latch 610 is in a set state. As shown, the SR latch 610 is set by an edge detect 615 of the PWM signal (e.g., as described with reference to FIG. 1A). For example, the S_pulldown1 may be triggered by the falling edge of the PWM signal. For example, the first stage 605 may be a fast turn-off state started by the PWM signal. In the depicted example, the first stage 305 may be ended (e.g., reset of the SR latch 610) when an integration of a detected source inductance voltage (VLS) is lower than a predetermined negative reference voltage (Vref1 620).

The time control logic 600 includes a second stage 625. In some implementations, the second stage 625 may be configured as a damping stage. For example, the second stage 625 may be synchronized with the PWM signal.

The time control logic 600 includes a third stage 630. The third stage 630 includes a second SR latch 635 connected to an output signal (S_pulldown3). As shown, the S_pullup3 is set when the derivation of the detected source inductance voltage (VLS) becomes higher than a predetermined positive reference voltage (Vref2 640). The S_pullup3 is reset by the PWM signal. Various embodiments may adaptively adjust a turn-off timing of the HS switch 220 based on the source inductance voltage.

FIG. 7 is an electrical schematic of a MSGCC having an exemplary Sense-FET Incorporated Device (SFID). In this example, a motor drive system 700 includes a MSGCC 705 having a HDM 710 and a LDM 715. Each of the HDM 710 and the LDM 715, as shown, is connected to one or more Sense-FET incorporated devices (SFIDs 720). For example, the MSGCC 705 may generate control signals to the SFIDs 720 to supply electric current to a load 725. For example, the SFIDs 720 may be the HSPP 195 with reference to FIG. 1B.

For example, each of the SFID 720 includes a main FET 730 and a Sense-FET 735. In some implementations, the Sense-FET 735 may occupy a small portion of a die area of a switch device (e.g., compared to the main FET 730 of a corresponding SFID). For example, the Sense-FET 735 may generate a sense signal 740 related to a main response of the main FET 730. In some implementations, the Sense-FET may generate a response that is a fraction (e.g., 1/100, 1/500, 1/1000, 1/5000, other fraction) of the main response.

In this example, the SFID 720 includes a sense resistor 745 connected between a main FET source pin 770 and a Sense-FET source pin. For example, the sense resistor 745 may generate the sense signal 740 (e.g., a sense voltage signal) for the MSGCC 705. For example, the MSGCC 705 may include a multi-stage driving scheme configured to generate the control signals based on the sense signal 740. In some examples, the multi-stage driving scheme may advantageously reduce the switching loss without sacrificing a transient voltage spike requirement.

The MSGCC 705, as shown, includes a timing control logic 750 in each of the HDM 710 and the LDM 715. The timing control logic 750 is connected to a gate terminal of each of three pullup transistors 755a, 755b, 755c. For example, a drain terminal of each of the three pullup transistors 755a, 755b, 755c is connected to a gate terminal of the SFIDs 720 of a high-side circuit 765. In some examples, the AACC 190 (FIG. 1B) may include the timing control logic 750, the first pullup transistor 755a-c, and the first pulldown transistor 760a-c.

The timing control logic 750 is connected to a gate terminal of each of three pulldown transistors 760a, 760b, 760c. For example, the timing control logic 750 may generate the gate signals for the multi-stage pullup transistors 755a-c or the pulldown transistors 760a-c. For example, a source terminal of each of the three pulldown transistors 760a, 760b, 760c is connected to the main FET source pin 770 of the SFIDs 720 of the high-side circuit 765. In some embodiments, the timing control logic 750 may include logic (e.g., analog and/or digital logics) to control gate signals to the three pullup transistors 755a-c, and the three pulldown transistors 760a-c. For example, the gate signals may control a response during turn-on and turn-off of the SFIDs 720.

In various implementations, the Sense-FET 735 may advantageously generate the sense signal 740 with a predetermined magnitude during a design phase. For example, the sense signal 740 may include a higher magnitude when the sense resistor 745 has an appropriate resistance value. For example, the higher magnitude of the sense signal 740 may advantageously provide better noise immunity properties.

In some examples, when the sense signal 740 is measured at a same node (e.g., at a driver return path connection), the motor drive system 700 may be simplified by reducing an extra level-shift circuit between high-side and low-side. For example, the reduction of the level shift circuit may advantageously reduce time delay for a corresponding feedback signal to be received by the timing control logic 750.

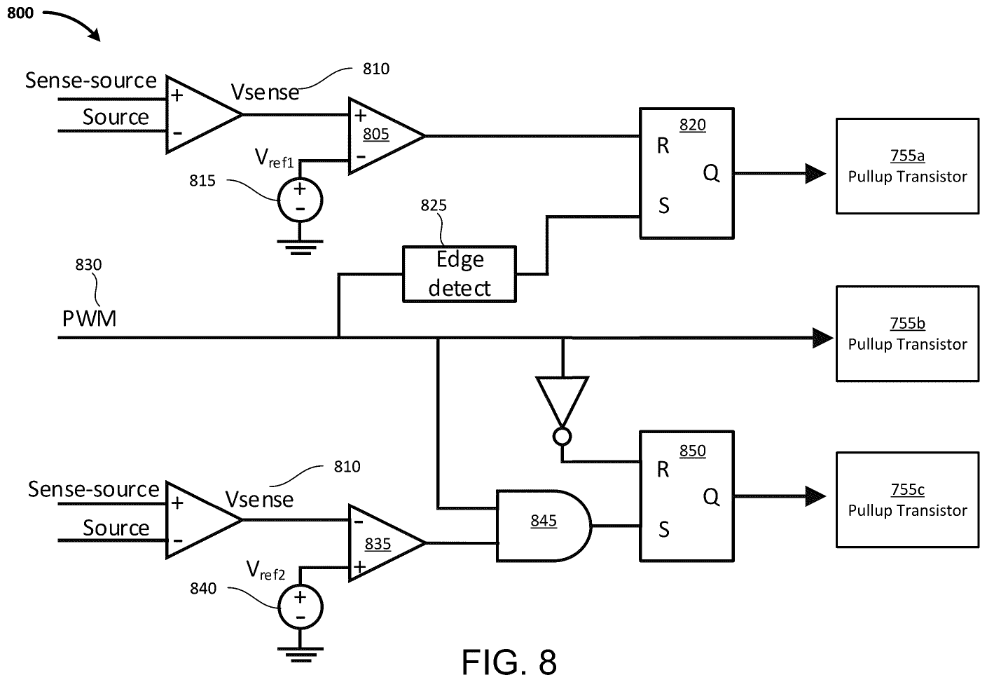

FIG. 8 is a block diagram depicting an exemplary time control turn-on logic (TCTONL 800). For example, the timing control logic 750 may generate the gate signals to the three pullup transistors 755a-c based on the TCTONL 800. For example, the TCTONL 800 may include an analog circuit. For example, analog components such as voltage comparators, edge detectors, logic gates, and SR latches, as shown in the depicted example may be used to generate timing signals in response to sensed voltages. In some examples, the TCTONL 800 may include software logic to be executed by a digital controller (e.g., a processor, a computing processing unit, a digital signal processor). For example, the software may monitor sensed voltage values and generate digital control signals using threshold detection and time-delay algorithms to sequentially activate the pullup transistors. In some examples, the TCTONL 800 may include a programmable logic device such as a field-programmable gate array (FPGA), which may be configured to perform the timing sequence logic in hardware with high precision and reconfigurability.

In this example, the TCTONL 800 generates control signals to activate/deactivate the pullup transistors 755a, 755b, 755c during the multi-stage turn-on process of the SFIDs 720. In a first stage, for example, the TCTONL 800 includes a first comparator 805 configured to generate a sense voltage 810 indicative of a sense-to-source potential. For example, the sense voltage 810 may be a voltage across a sensing resistor between a power device source pin (e.g., the main FET source pin 770) and a sense-source pin (e.g., a source pin of the Sense-FET 735). For example, the sense voltage 810 may be a difference between the sense signal 740 and a source voltage of the main FET 730.

The sense voltage 810 is compared with a first reference voltage (V_ref1 815). A first logic stage may assert a signal to reset a first SR latch 820 when the sense voltage exceeds the V_refl 815. An output of the first SR latch 820 may control the gate of the first pullup transistor 755a. For example, the first pullup transistor 755a may include a low pullup resistor to facilitate a fast turn-on stage. As shown, an edge detector 825 may detect a rising edge of a PWM signal 830 that may set the first SR latch 820 and initiate the first stage.

In a second stage, the gate signals controlling the second pullup transistor 755b may be synchronized with the PWM signal 830. For example, the PWM signal may directly control the activation of the second pullup transistor 755b. In some implementations, the second pullup transistor 755b may include a high pullup resistor. For example, the high pullup resistor may advantageously provide a damping effect following the first stage. Various implementations may advantageously reduce gate voltage overshoot.

In a third stage, the TCTONL 800 may include a second comparator 835 configured to compare the sense voltage 810 with a second reference voltage (V_ref2 840). When the sense voltage 810 drops below V_ref2 840, the comparator output may indicate that the switching node voltage has slewed. This signal may be logically combined with the PWM signal 830 using an AND gate 845 to generate a set signal to a second SR latch 850. The Q output of the second SR latch 850 may drive the gate of the third pullup transistor 755c. The third pullup transistor 755c may include a medium pullup resistor. The second SR latch 850 may be reset by an inverse of the PWM signal 830. For example, the medium pullup resistor may advantageously provide fast enhance to the SFIDs 720 (e.g., by speeding up turn-on after the switching node voltage slew) in the later phase of a turn-on transition.

In some implementations, each of the three stages may advantageously be triggered based on a real-time logic control as a function of the sense signal 740. For example, the TCTONL 800 may advantageously be adaptively controlled across different phases of switching based on real-time device response.

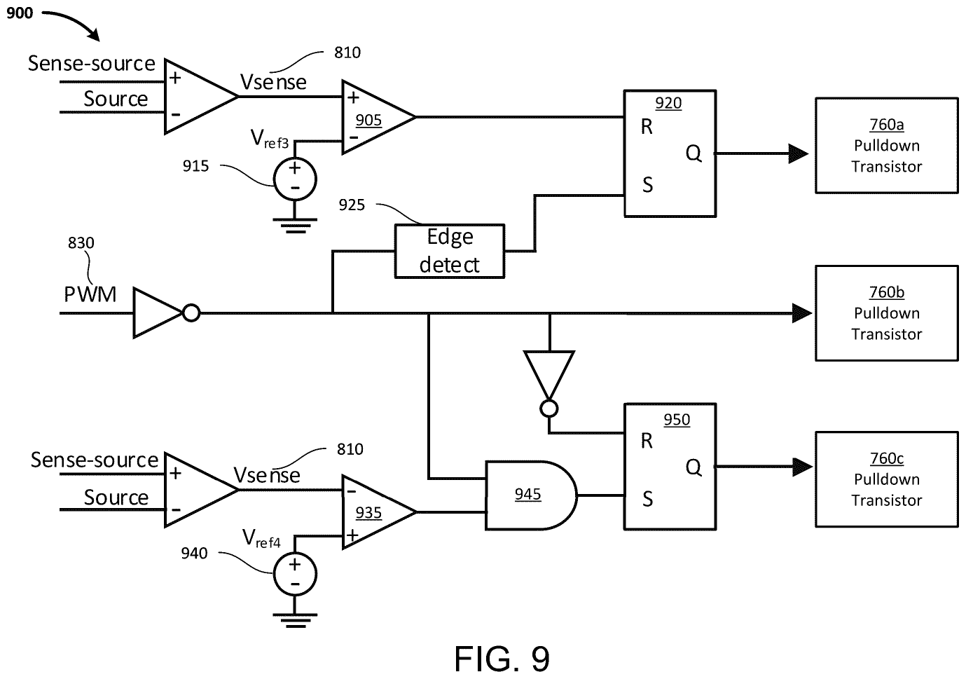

FIG. 9 is a block diagram depicting an exemplary time control turn-off logic (TCTOFL 900). For example, the timing control logic 750 may generate gate signals to the three pulldown transistors 760a-c based on the TCTOFL 900. For example, the TCTOFL 900 may include an analog circuit. Analog components such as voltage comparators, edge detectors, logic gates, and SR latches, as shown in the depicted example, may be used to generate timing signals in response to sensed voltages. In some examples, the TCTOFL 900 may include software logic to be executed by a digital controller (e.g., a processor, a computing processing unit, a digital signal processor). For example, the software may monitor sensed voltage values and generate digital control signals using threshold detection and time-delay algorithms to sequentially activate the pulldown transistors. In some examples, the TCTOFL 900 may include a programmable logic device (e.g., FPGA) configured to perform the timing sequence logic in hardware with high precision and reconfigurability.

In this example, the TCTOFL 900 generates control signals to activate/deactivate the pulldown transistors 760a, 760b, 760c during the multi-stage turn-off process of the SFIDs 720. In a first stage, for example, the TCTOFL 900 includes a comparator 905 configured to generate a sense voltage 810 indicative of a sense-to-source potential. For example, the sense voltage 810 may be a difference between the sense signal 740 and a source voltage of the main FET 730.

The sense voltage 810 is compared with a reference voltage (V_ref3 915). The comparison result may assert a signal to reset a third SR latch 920 when the sense voltage 810 exceeds the V_ref3 915. An output of the third SR latch 920 may control the gate of the first pulldown transistor 760a. For example, the first pulldown transistor 760a may include a low pulldown resistor to facilitate a fast turn-off stage. For example, an edge detector 925 may detect a falling edge of the PWM signal 830 and generate a signal to set the third SR latch 920, initiating the first turn-off stage.

In a second stage, the gate signals controlling the second pulldown transistor 760b may be (inversely) synchronized with the PWM signal 830. For example, the PWM signal 830 may be inverted. For example, the inverse PWM signal may be used to activate the second pulldown transistor 760b. In some implementations, the second pulldown transistor 760b may include a high pulldown resistor. For example, the high pulldown resistor may provide a damping effect following the first stage. For example, the high pulldown resistor may advantageously prevent excessive gate undershoot and/or oscillation.

In a third stage, the TCTOFL 900 may include a second comparator 935 configured to compare the sense voltage 810 with another reference voltage (V_ref4 940). When the sense voltage 810 drops below V_ref4 940, the comparator output may indicate that the switching node voltage has slewed sufficiently. This signal may be logically combined with the inverted PWM signal using an AND gate 945 to generate a set signal to a fourth SR latch 950. An output of the fourth SR latch 950 may drive the gate of the third pulldown transistor 760c. For example, the fourth SR latch 950 may be reset by the PWM signal 830. The third pulldown transistor 760c may include a medium pulldown resistor. For example, the medium pulldown resistor may advantageously provide a fast turn-off enhancement after the switching node voltage slew. For example, various implementations may advantageously generate timing signals (e.g., the gate signals) adaptively for a multi-stage driving scheme under various (e.g., unpredicted, unknown, uncertain) load conditions.

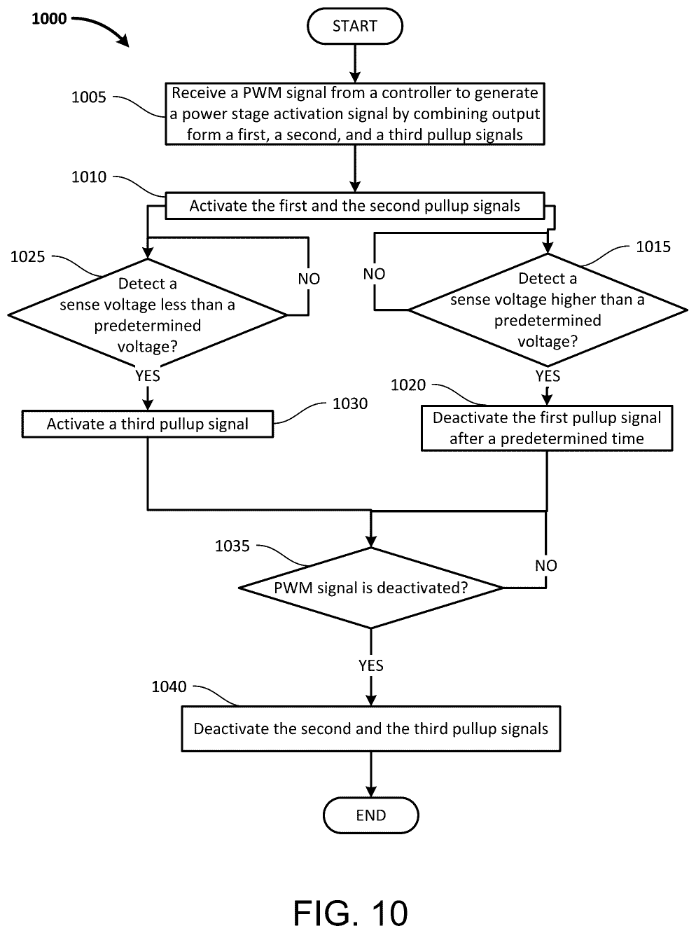

FIG. 10 is a flowchart illustrating an exemplary adaptive power stage turn-on method 1000. For example, the method 1000 may be performed by the timing control logic 750. In step 1005, the method 1000 begins when a PWM signal is received from a controller to generate a power stage activation signal by combining output from a first, a second, and a third pullup signals. For example, the timing control logic 750 of the MSGCC 705 may receive the PWM signal and begin generating gate signals to activate the pullup transistors 755a-c.

In step 1010, the first and the second pullup signals are activated. For example, the timing control logic 750 may activate gate signals to turn on the first and second pullup transistors 755a and 755b in response to the received PWM signal.

At a decision point 1015, it is determined whether a sense voltage higher than a predetermined voltage is detected. For example, the timing control logic 750 may compare the sense voltage 810 with a first threshold (e.g., V_ref1 815). If a higher voltage is detected, in step 1020, the first pullup signal is deactivated after a predetermined time. For example, the timing control logic 750 may assert a reset signal to a corresponding latch (e.g., the first SR latch 820) to turn off the first pullup transistor 755a after a time delay. If the condition is not met, the decision point 1015 is repeated.

Operating in parallel, at a decision point 1025, it is determined whether a sense voltage lower than another predetermined voltage is detected. For example, the timing control logic 750 may compare the sense voltage 810 with a second threshold (e.g., V_ref2 840). If the voltage exceeds the threshold, in step 1030, the third pullup signal is activated. For example, the timing control logic 750 may set a third SR latch (e.g., the second SR latch 850) to activate the third pullup transistor 755c. If the voltage is not higher than the threshold, the decision point 1025 is repeated.

At a decision point 1035, it is determined whether the PWM signal is deactivated. For example, the timing control logic 750 may detect the trailing edge of the PWM signal. If the PWM signal is deactivated, in step 1040, the second and the third pullup signals are deactivated. For example, the timing control logic 750 may deactivate gate signals to the pullup transistors 755b and 755c by resetting corresponding SR latches, and the method 1000 ends.

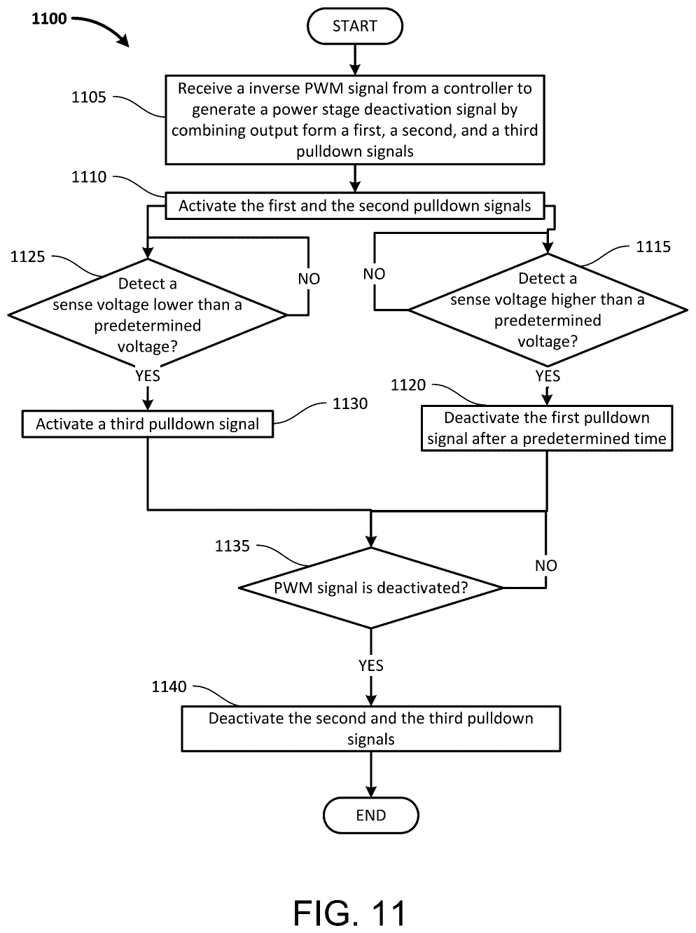

FIG. 11 is a flowchart illustrating an exemplary adaptive power stage turn-off method 1100. For example, the method 1100 may be performed by the timing control logic 750. In step 1105, an inverse PWM signal is received from a controller to generate a power stage deactivation signal by combining output from a first, a second, and a third pulldown signals. For example, the timing control logic 750 of the MSGCC 705 may receive the inverted PWM signal and begin generating gate signals to deactivate the SFIDs 720 using a multi-stage pulldown strategy.

In step 1110, the first and the second pulldown signals are activated. For example, the timing control logic 750 may generate gate signals to activate the first and second pulldown transistors 760a and 760b in response to the inverse PWM signal.

At a decision point 1115, it is determined whether a sense voltage is higher than a predetermined voltage is detected. For example, the timing control logic 750 may compare the sense voltage 810 with a threshold (e.g., V_ref3 915). If the sense voltage is higher than the threshold, in step 1120, the first pulldown signal is deactivated after a predetermined time. For example, the timing control logic 750 may reset the third SR latch 920 after a time delay to deactivate the first pulldown transistor 760a. If the voltage is not higher than the threshold, the decision point 1115 is repeated.

Operating in parallel, at a decision point 1125, it is determined whether the sense voltage is lower than a predetermined voltage. For example, the timing control logic 750 may compare the sense voltage 810 with a second threshold (e.g., V_ref4 940). If the voltage is lower than the threshold, in step 1130, the third pulldown signal is activated. For example, the timing control logic 750 may assert a set signal to a fourth SR latch 950 to activate the third pulldown transistor 760c. If the condition is not met, the decision point 1125 is repeated.

At a decision point 1135, it is determined whether the PWM signal is deactivated. For example, the timing control logic 750 may detect the end of the PWM signal cycle when the PWM signal 830 is negative. If the PWM signal is deactivated, in step 1140, the second and the third pulldown signals are deactivated. For example, the timing control logic 750 may deactivate the second and third pulldown transistors 760b and 760c by resetting their corresponding SR latches, and the method 1100 ends.

Although various embodiments have been described with reference to the figures, other embodiments are possible. For example, various transistors may be depicted and/or described to be in p-channel MOSFETs or n-channel MOSFETs. In some implementations, these transistors may be adapted to be implemented in different types of MOSFETs by changing some connections in the circuitry.

Although an exemplary system has been described with reference to the figures, other implementations may be deployed in other industrial, scientific, medical, commercial, and/or residential applications.

In some implementations, the APCS 100 may be used in industrial machinery. For example, the motor 105 may include high-power AC motors used to drive pumps and compressors in industries including, for example, oil and gas, water treatment, and chemical processing. For example, the motor 105 may power conveyor systems for moving heavy materials and/or products across a distance.

In some implementations, the APCS 100 may be used to drive motors in mining equipment. For example, the motor 105 may be configured to operate large-scale excavation equipment and drills. For example, the APCS 100 may be configured to drive crushing and grinding equipment in mining operations.

In some implementations, the APCS 100 may be used to drive high-power AC motors in induction heating systems (e.g., furnaces for melting and processing metals at high temperatures). In some examples, the APCS 100 may be used to drive a motor for propulsion of electric trains and locomotives.

In some implementations, the APCS 100 may be used to drive motors in a factory (e.g., in manufacturing applications). In some examples, the APCS 100 may be configured to drive a motor to operate construction equipment including, for example, cranes and hoists for lifting and moving heavy loads.

In an illustrative aspect, a gate drive timing control unit may include a control output configured to generate a power stage activation signal to control a power stage output. For example, the control output may be operably coupled to a switch device may include a power metal-oxide-semiconductor field-effect transistor (power MOSFET). For example, the power stage activation signal may be configured to control an output current of the power MOSFET to a load. For example, the gate drive timing control unit may include a sense field-effect transistor (Sense-FET) circuit configured to generate a sense voltage signal related to a source voltage of the power MOSFET. For example, a sense gate terminal of the Sense-FET may be connected in parallel to a main gate terminal of the power MOSFET.

For example, the gate drive timing control unit may include a sense resistor may be connected between a main source terminal of the power MOSFET and a sense source terminal of the Sense-FET. For example, the gate drive timing control unit may include a sense input configured to receive the sense voltage signal of the switch device. For example, the gate drive timing control unit may include a timing control logic.

For example, the timing control logic may include at least three pullup transistors electrically connected to the control output in parallel. For example, the timing control logic may be configured to generate the power stage activation signal as a function of the sense voltage signal. For example, a first pullup transistor of the at least three pullup transistors may be configured to be activated when a PWM signal may be received, and deactivated when the sense voltage signal may be greater than or equal to a first predetermined threshold. For example, a second pullup transistor of the at least three pullup transistors may be configured to be synchronized with the PWM signal. For example, a third pullup transistor of the at least three pullup transistors may be configured to be activated when the sense voltage signal drops below a second predetermined threshold.

For example, the timing control logic may include at least three pulldown transistors electrically connected to a source terminal of the power MOSFET in parallel. For example, a first pulldown transistor of the at least three pulldown transistors may be configured to be activated when an inverse of the PWM signal may be received, and deactivated when the sense voltage signal may be greater than or equal to a third predetermined threshold. For example, a second pulldown transistor of the at least three pulldown transistors may be configured to be synchronized with the inverse of the PWM signal. For example, a third pulldown transistor of the at least three pulldown transistors may be configured to be activated when the sense voltage signal drops below a fourth predetermined threshold.

For example, the Sense-FET may be configured to generate, at the sense source terminal, an output current as a function of a predetermined fraction of a load current generated at the main source terminal. For example, the predetermined fraction may be less than 0.001.

For example, a low pullup resistor may be connected between a first output of the first pullup transistor and the control output. For example, a high pullup resistor may be connected between a second output of the second pullup transistor and the control output. For example, a medium pullup resistor may be connected between a third output of the third pullup transistor and the control output.

For example, a low pulldown resistor may be connected between a fourth output of the first pulldown transistor and the control output. For example, a high pulldown resistor may be connected between a fifth output of the second pulldown transistor and the control output. For example, a medium pulldown resistor may be connected between a sixth output of the third pulldown transistor and the control output.

For example, the control output may be operably coupled to a plurality of the switch device. For example, the timing control logic may include an analog circuit. For example, the timing control logic may be implemented in a digital controller.

For example, a multiple-stage pullup pulldown controlling unit may include a high side gate driver that may include the gate drive timing control unit. For example, a first drain terminal of the power MOSFET connected to the high side gate driver may be operably coupled to a voltage input. For example, a multiple-stage pullup pulldown controlling unit may include a high side gate driver that may include the gate drive timing control unit that a low side gate driver. For example, the low side gate driver may include a second gate drive timing control unit. For example, a second drain terminal of the power MOSFET connected to the low side gate driver may be operably coupled to the source terminal of the power MOSFET connected to the high side gate driver. For example, the low side gate driver may include the source terminal of the power MOSFET connected to the low side gate driver may be connected to a ground terminal.

In an illustrative aspect, a gate drive timing control unit may include a control output configured to generate a power stage activation signal to control a power stage output. For example, the control output may be operably coupled to a switch device comprising a power metal-oxide-semiconductor field-effect transistor (power MOSFET). For example, the power stage activation signal may be configured to control an output current of the power MOSFET to a load. For example, the gate drive timing control unit may include a sense input configured to receive a sense voltage signal of the switch device. For example, the sense voltage signal may have a predetermined relationship with the power stage output.

For example, the gate drive timing control unit may include a timing control logic configured to operate the control output as a function of the sense input such that the power stage output is adaptively controlled to reduce turn-on loss of the MOSFET while keeping a low transient voltage spike.

For example, the timing control logic may include at least three pullup transistors electrically connected to the control output in parallel, and may be configured to generate the power stage activation signal as a function of the sense voltage signal. For example, a first pullup transistor of the at least three pullup transistors may be configured to be activated when a PWM signal may be received, and deactivated when the sense voltage signal may be greater than or equal to a first predetermined threshold. For example, a second pullup transistor of the at least three pullup transistors may be configured to be synchronized with the PWM signal. For example, a third pullup transistor of the at least three pullup transistors may be configured to be activated when the sense voltage signal drops below a second predetermined threshold.

For example, the gate drive timing control unit may include at least three pulldown transistors electrically connected to a source terminal of the power MOSFET in parallel. For example, a first pulldown transistor of the at least three pulldown transistors may be configured to be activated when an inverse of the PWM signal may be received, and deactivated when the sense voltage signal may be greater than or equal to a third predetermined threshold. For example, a second pulldown transistor of the at least three pulldown transistors may be configured to be synchronized with the inverse of the PWM signal. For example, a third pulldown transistor of the at least three pulldown transistors may be configured to be activated when the sense voltage signal drops below a fourth predetermined threshold.

For example, the switch device further may include a sense field-effect transistor (Sense-FET) circuit configured to generate the sense voltage signal. For example, a sense gate terminal of the Sense-FET may be connected in parallel to a main gate terminal of the power MOSFET. For example, a sense resistor may be connected between a main source terminal of the power MOSFET and a sense source terminal of the Sense-FET.

For example, the Sense-FET may be configured to generate, at the sense source terminal, a predetermined fraction of the current of the main source terminal. For example, the predetermined fraction may be less than 0.001.

For example, a low pullup resistor may be connected between a first output of the first pullup transistor and the control output. For example, a high pullup resistor may be connected between a second output of the second pullup transistor and the control output. For example, a medium pullup resistor may be connected between a third output of the first pullup transistor and the control output.

For example, a low pulldown resistor may be connected between a fourth output of the first pulldown transistor and the control output. For example, a high pulldown resistor may be connected between a fifth output of the second pulldown transistor and the control output. For example, a medium pulldown resistor may be connected between a sixth output of the third pulldown transistor and the control output.

For example, the control output may be operably coupled to a plurality of the switch device.

For example, the timing control logic may include an analog circuit.

For example, the timing control logic may be implemented in a digital controller.

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.

What is claimed is:

1. A gate drive timing control unit comprising:
a control output configured to generate a power stage activation signal to control a power stage output, wherein the control output is operably coupled to a switch device comprising:
a power metal-oxide-semiconductor field-effect transistor (power MOSFET), wherein the power stage activation signal is configured to control an output current of the power MOSFET to a load; and,
a sense field-effect transistor (Sense-FET) circuit configured to generate a sense voltage signal related to a source voltage of the power MOSFET, wherein:
a sense gate terminal of the Sense-FET is connected in parallel to a main gate terminal of the power MOSFET, and,
a sense resistor is connected between a main source terminal of the power MOSFET and a sense source terminal of the Sense-FET;
a sense input configured to receive the sense voltage signal of the switch device; and,
a timing control logic comprising:
at least three pullup transistors electrically connected to the control output in parallel, and are configured to generate the power stage activation signal as a function of the sense voltage signal, wherein:
a first pullup transistor of the at least three pullup transistors is configured to be activated when a PWM signal is received, and deactivated when the sense voltage signal is greater than or equal to a first predetermined threshold;
a second pullup transistor of the at least three pullup transistors is configured to be synchronized with the PWM signal; and,
a third pullup transistor of the at least three pullup transistors is configured to be activated when the sense voltage signal drops below a second predetermined threshold; and,
at least three pulldown transistors electrically connected to a source terminal of the power MOSFET in parallel, wherein:
a first pulldown transistor of the at least three pulldown transistors is configured to be activated when an inverse of the PWM signal is received, and deactivated when the sense voltage signal is greater than or equal to a third predetermined threshold;
a second pulldown transistor of the at least three pulldown transistors is configured to be synchronized with the inverse of the PWM signal; and,
a third pulldown transistor of the at least three pulldown transistors is configured to be activated when the sense voltage signal drops below a fourth predetermined threshold.

2. The gate drive timing control unit of claim 1, wherein the Sense-FET is configured to generate, at the sense source terminal, an output current as a function of a predetermined fraction of a load current generated at the main source terminal.

3. The gate drive timing control unit of claim 2, wherein the predetermined fraction is less than 0.001.

4. The gate drive timing control unit of claim 1, wherein:
a low pullup resistor is connected between a first output of the first pullup transistor and the control output;
a high pullup resistor is connected between a second output of the second pullup transistor and the control output; and,
a medium pullup resistor is connected between a third output of the third pullup transistor and the control output.

5. The gate drive timing control unit of claim 1, wherein:
a low pulldown resistor is connected between a fourth output of the first pulldown transistor and the control output;
a high pulldown resistor is connected between a fifth output of the second pulldown transistor and the control output; and,
a medium pulldown resistor is connected between a sixth output of the third pulldown transistor and the control output.

6. The gate drive timing control unit of claim 1, wherein the control output is operably coupled to a plurality of the switch device.

7. The gate drive timing control unit of claim 1, wherein the timing control logic comprises an analog circuit.

8. The gate drive timing control unit of claim 1, wherein the timing control logic is implemented in a digital controller.

9. A multiple-stage pullup pulldown controlling unit, comprising:
a high side gate driver comprises the gate drive timing control unit of claim 1, wherein a first drain terminal of the power MOSFET connected to the high side gate driver is operably coupled to a voltage input; and,
a low side gate driver comprises the gate drive timing control unit of claim 1, wherein:
a second drain terminal of the power MOSFET connected to the low side gate driver is operably coupled to the source terminal of the power MOSFET connected to the high side gate driver; and,
the source terminal of the power MOSFET connected to the low side gate driver is connected to a ground terminal.

10. A gate drive timing control unit comprising:
a control output configured to generate a power stage activation signal to control a power stage output, wherein the control output is operably coupled to a switch device comprising a power metal-oxide-semiconductor field-effect transistor (power MOSFET), wherein the power stage activation signal is configured to control an output current of the power MOSFET to a load;
a sense input configured to receive a sense voltage signal of the switch device, wherein the sense voltage signal has a predetermined relationship with the power stage output; and,
a timing control logic configured to operate the control output as a function of the sense input such that the power stage output is adaptively controlled to reduce turn-on loss of the MOSFET while keeping a low transient voltage spike.

11. The gate drive timing control unit of claim 10, wherein the timing control logic comprises:
at least three pullup transistors electrically connected to the control output in parallel, and are configured to generate the power stage activation signal as a function of the sense voltage signal, wherein:
a first pullup transistor of the at least three pullup transistors is configured to be activated when a PWM signal is received, and deactivated when the sense voltage signal is greater than or equal to a first predetermined threshold;
a second pullup transistor of the at least three pullup transistors is configured to be synchronized with the PWM signal; and,
a third pullup transistor of the at least three pullup transistors is configured to be activated when the sense voltage signal drops below a second predetermined threshold.

12. The gate drive timing control unit of claim 11, further comprises at least three pulldown transistors electrically connected to a source terminal of the power MOSFET in parallel, wherein:
a first pulldown transistor of the at least three pulldown transistors is configured to be activated when an inverse of the PWM signal is received, and deactivated when the sense voltage signal is greater than or equal to a third predetermined threshold;
a second pulldown transistor of the at least three pulldown transistors is configured to be synchronized with the inverse of the PWM signal; and,
a third pulldown transistor of the at least three pulldown transistors is configured to be activated when the sense voltage signal drops below a fourth predetermined threshold.

13. The gate drive timing control unit of claim 10, wherein the switch device further comprises a sense field-effect transistor (Sense-FET) circuit configured to generate the sense voltage signal, wherein:
a sense gate terminal of the Sense-FET is connected in parallel to a main gate terminal of the power MOSFET, and,
a sense resistor is connected between a main source terminal of the power MOSFET and a sense source terminal of the Sense-FET.

14. The gate drive timing control unit of claim 13, wherein the Sense-FET is configured to generate, at the sense source terminal, a predetermined fraction of the current of the main source terminal.

15. The gate drive timing control unit of claim 14, wherein the predetermined fraction is less than 0.001.

16. The gate drive timing control unit of claim 11, wherein:
a low pullup resistor is connected between a first output of the first pullup transistor and the control output;
a high pullup resistor is connected between a second output of the second pullup transistor and the control output; and,
a medium pullup resistor is connected between a third output of the first pullup transistor and the control output.

17. The gate drive timing control unit of claim 12, wherein:
a low pulldown resistor is connected between a fourth output of the first pulldown transistor and the control output;
a high pulldown resistor is connected between a fifth output of the second pulldown transistor and the control output; and,
a medium pulldown resistor is connected between a sixth output of the third pulldown transistor and the control output.

18. The gate drive timing control unit of claim 10, wherein the control output is operably coupled to a plurality of the switch device.

19. The gate drive timing control unit of claim 10, wherein the timing control logic comprises an analog circuit.

20. The gate drive timing control unit of claim 10, wherein the timing control logic is implemented in a digital controller.
